(19) United States
(12) Patent Application Publication
(10) Pub. No.: US 2024/0404832 A1
(43) Pub. Date: Dec. 5, 2024

(54) WET TOOL KIT FOR FORMING SEMICONDUCTOR STRUCTURE AND CMOS IMAGE SENSOR EMPLOYING SAME

(71) Applicant: Taiwan Semiconductor Manufacturing Company LTD, Hsinchu (TW)

(72) Inventors: Chenchia Hung, Kaohsiung City (TW); Keng-Ying Liao, Tainan City (TW); Po-Zen Chen, Tainan City (TW); Chih Wei Sung, Kaohsiung (TW); Chien-Chung Chen, Kaohsiung (TW)

(21) Appl. No.: 18/204,995

(22) Filed: Jun. 2, 2023

(51) Int. Cl. H01L 21/306; H01L 27/146

(52) U.S. Cl. CPC H01L 21/30604; H01L 27/14614; H01L 27/14643; H01L 27/14689

(57) ABSTRACT

A method of fabricating a semiconductor structure includes disposing a metal catalyst on a surface of a semiconductor. Thereafter, metal assisted chemical etching is performed, including holding the semiconductor immersed in an etchant solution and catalyzing an etching chemical reaction between the etchant solution and the semiconductor using the metal catalyst to etch the semiconductor to form a channel in the semiconductor. During at least a portion of the metal assisted chemical etching the semiconductor is held immersed in the etchant solution with a surface normal of the surface of the semiconductor at a non-zero angle respective to gravity. In some examples, an orientation of the semiconductor is changed during the metal assisted chemical etching to form the channel in the semiconductor with at least one bend or curved portion.

### BACKGROUND

The following relates to the semiconductor structure fabrication arts, semiconductor device fabrication arts, image sensor arts, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates aspects of a metal assisted chemical etching process, including: the disposing of a metal catalyst on a surface of a semiconductor (part (A)); initial descent of the metal catalyst into the semiconductor during the metal assisted chemical etching along with indications of some representative suitable etching reactions (parts (B) and (C)); formation of an etched channel by continued metal assisted chemical etching (part (D)); and an approach for enabling etching of the channel with a substantially arbitrary geometry (part (E)).

FIGS. 2, 3, 4, and 5 diagrammatically illustrate metal assisted chemical etching of a bent channel in a semiconductor.

FIG. 6 diagrammatically illustrates a metal assisted chemical etching method for etching slanted and/or non-linear channels is shown by way of a flowchart.

FIGS. 7, 8, and 9 diagrammatically illustrate an example of a suitable semiconductor process tool for implementing etching of nonlinear channels by metal assisted chemical etching with controlled orientation of the semiconductor in the context of an automated semiconductor manufacturing process workflow.

FIG. 10 diagrammatically illustrates the geometry observed by cross-sectional transmission electron microscopy (XTEM) of straight slanted channels formed in silicon using metal assisted chemical etching as disclosed herein.

FIG. 11 diagrammatically illustrates the geometry observed by XTEM of an array of nonlinear channels formed in silicon using metal assisted chemical etching as disclosed herein.

FIG. 12 shows a diagrammatic sectional view of a complementary metal-oxide-semiconductor (CMOS) image sensor.

FIG. 13 shows a top view of a grouping of four CMOS image sensors of FIG. 12 arranged to share a common N-type doped region.

FIGS. 14 and 15 diagrammatically illustrate steps in fabricating the vertical transfer gate (VTG) of the CMOS image sensor of FIG. 12.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Wet chemical etching is used in a wide range of semiconductor fabrication processes. Wet chemical etching is low cost, easily scalable to large-area wafers, and can provide a high degree of precision in terms of etch rate, depth, and other metrics. However, wet etching has certain limitations. Wet etching is typically either isotropic, or tends to preferentially etch a crystalline material along certain crystalline planes. This can significantly limit the effectiveness of wet chemical etching for generating etched openings or spaces of specific desired geometries. For etching of highly controlled target geometries, dry etching can be used since dry etching can be highly anisotropic (directional). Even with dry etching however, control of the etched geometry to match a target geometry can be challenging.

A useful target etch geometry for some applications would be a channel, i.e., a columnar opening, etched into the material with a specific channel direction. Typically, etching of high aspect ratio channels (i.e., channels with a long channel length compared with the diameter or other cross-sectional metric of the channel) is not readily achieved with wet chemical etching. Dry etching with suitable photolithographic masking can provide for etching channels, but the directional control can be limited, and it may be difficult to achieve a constant channel diameter (or other cross-section) for longer channel lengths. Even more challenging would be formation of a curved channel, or a bent channel (e.g., a portion going straight down from the surface, followed by a section angled away from the initial straight-down portion), or more generally a channel of arbitrary geometry in which the channel direction changes at abrupt points along the channel or curves at specific points along the channel.

A further consideration in etching channels is etch rate, as a channel is a high aspect ratio feature.

Disclosed herein are approaches for wet etching of channels with specific directions, wet etching of bent channels, wet etching of curved channels, or various combinations thereof. The disclosed approaches advantageously utilize low cost wet chemical etching to achieve this high degree of control. In illustrative embodiments for wet etching of channels of substantially arbitrary geometry in silicon, the approaches advantageously utilize a low cost and readily obtainable wet etchant solution comprising a mixture of hydrogen fluoride (HF) and hydrogen peroxide (H₂O₂). High etch rates are also readily achievable.

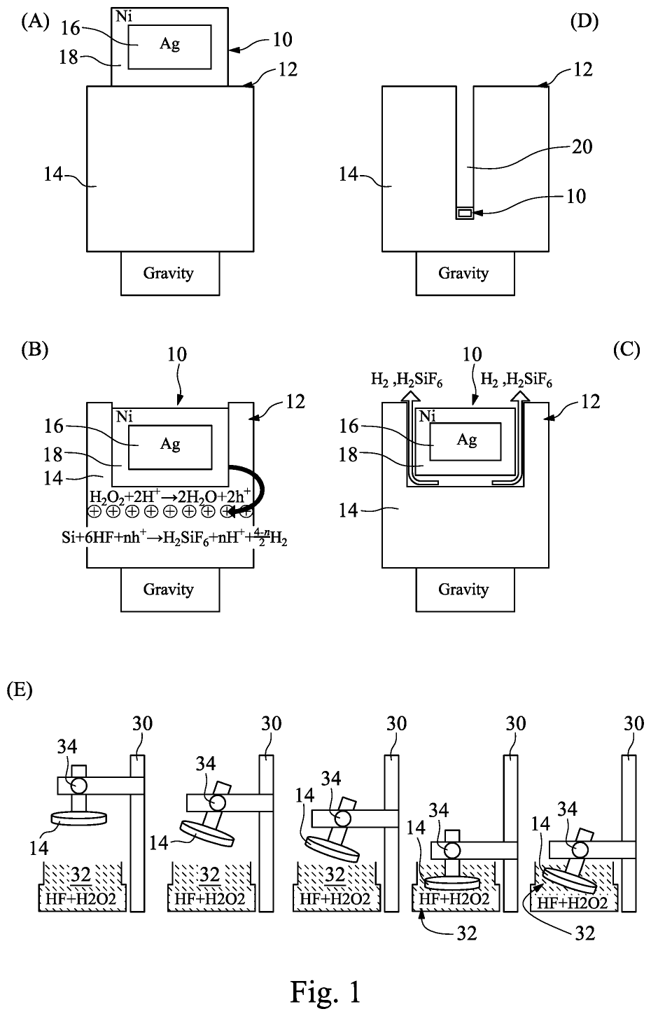

With reference to FIG. 1 part (A), the wet chemical etching approaches disclosed herein utilize metal assisted chemical etching. In this approach, a metal catalyst 10 is disposed on a surface 12 of a semiconductor 14. In illustrative FIG. 1 part (A), the semiconductor is silicon and the metal catalyst 10 is a silver (Ag) region, ball, particle, nanoparticle, slug, or other silver mass 16 that in the illustrative example is coated with a nickel (Ni) coating 18 to aid adhesion to the surface of the silicon. While illustrative FIG. 1 part (A) and parts (B) and (C) illustrate the metal catalyst as rectangular in cross-section, it may more generally be spherical, ovoid, disk-shaped, irregularly shaped (e.g. a particle or nanoparticle), or so forth. In metal assisted chemical etching, the semiconductor 14 with the metal catalyst 10 disposed on its surface 12 is immersed in an etchant solution (not shown in FIG. 1) such as an aqueous HF/H₂O₂ etchant solution, and the metal catalyst 10 catalyzes an etching chemical reaction between the etchant solution and the semiconductor 14. This is diagrammatically indicated in FIG. 1 part (B), where some suitable metal-catalyzed etching reactions (assuming silicon as the semiconductor and an aqueous HF/H₂O₂ etchant solution) are:

$${H}_{2} {O}_{2} + 2 {H}^{+} \to {H}_{2} O + 2 {h}^{+} \\ and \qquad ( 1 )$$

$$Si + 6 HF + {nh}^{+} \to {H}_{2} {SiF}_{6} + {n H}^{+} + \frac{4 - n}{2} {H}_{2} \qquad ( 2 )$$

where h⁺ denotes a hole and n is a positive even integer. Note that because the metal catalyst (e.g. Ag) operates to catalyze these reactions, but does as a catalyst is not itself a reactant in these chemical reactions. As diagrammatically shown in FIG. 1 part (C), the reaction products are aqueous hydrogen (H₂) and hexafluorosilicic acid (H₂SiF₆). Under force of gravity the reaction products H₂ and H₂SiF₆ are expelled from the interface between the metal catalyst 10 and the silicon 14. As the silicon material is etched away, and the metal catalyst 10 descends downward into the silicon 14 under the force of gravity, as diagrammatically indicated by the descended position of the metal catalyst 10 into the silicon 14 shown in FIG. 1 parts (B) and (C) when compared with part (A). The catalyzed reaction occurs solely (or at least predominantly) underneath the metal catalyst 10 where contact between the catalyst 10 and the silicon 14 is most intimate, so as the metal assisted chemical etching proceeds the metal catalyst 10 descends deeper into the silicon 14, leaving an etched channel 20 above it, as diagrammatically shown in FIG. 1 part (D) (which is “zoomed out” as compared with parts (A)-(C)). The overall metal assisted chemical etching reaction is given by:

$$Si + 6 HF + \frac{n}{2} {H}_{2} {O}_{2} \to {H}_{2} S i {F}_{6} + {n H}_{2} O + \frac{4 - n}{2} {H}_{2} \qquad ( 3 )$$

However, as seen in FIG. 1 part (D), the channel 20 that is etched by this metal assisted chemical etching process is a straight, vertically oriented channel. The length of the channel 20 can be controlled by the etch time (i.e., the time that the semiconductor 14 remains immersed in the etching solution) along with the etch rate which is controlled by parameters such as the H₂/H₂O₂ ratio of the etching solution, the choice of metal catalyst, and other factors such as the temperature. The cross-section of the channel 20 can be controlled by the area of the metal catalyst 10. However, the resulting channel 20 is vertically straight as governed by gravity. Hence, the metal assisted chemical etching described with reference to FIG. 1 parts (A)-(D) cannot, by itself, provide the desired wet etching of channels with specific directions, wet etching of bent channels, wet etching of curved channels, or more generally wet etching of channels of substantially arbitrary geometry.

With reference now to FIG. 1 part (E), as disclosed herein these limitation of the metal assisted chemical etching of FIG. 1 parts (A)-(D) can be overcome by further providing an apparatus 30 for controlling the orientation of the semiconductor 14 (e.g., shown diagrammatically as a silicon wafer 14 in part (E)) respective to gravity when the silicon wafer 14 is immersed in the etchant solution 32 (explicitly shown only in part (E) of FIG. 1). Note that the silicon wafer 14 has the metal catalyst 10 (or an array of balls, areas, particles, nanoparticles, or other units of metal catalyst 10) disposed on its upper surface. The illustrative apparatus 30 includes a pivot 34 to enable the orientation of the silicon wafer 14 to be adjusted in a controllable manner.

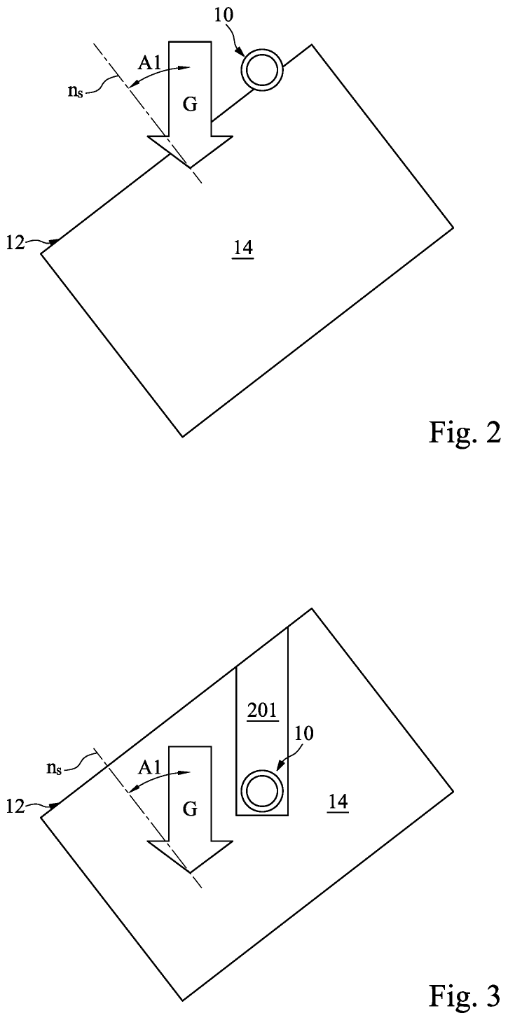

With reference now to FIGS. 2-5, an example of this approach for etching a bent channel in silicon is diagrammatically shown. FIG. 2 diagrammatically shows the semiconductor 14 with the catalyst metal 10 disposed thereon, before initiation of metal assisted chemical etching. Notably, the surface normal nₛ of the surface 12 of the semiconductor 14 is oriented at a nonzero angle A1 relative to gravity G (diagrammatically indicated by an arrow labeled G in FIGS. 2-5).

FIG. 3 diagrammatically shows the semiconductor 14 at a time t=t₁ after the time t=0 when the wafer 14 with the metal catalyst 10 disposed thereon has been immersed in the etchant solution to initiate the metal assisted chemical etching. (Put another way, FIG. 3 shows the semiconductor 14 after the metal assisted chemical etching has been proceeding for a time duration t₁). As shown in FIG. 3, the metal assisted chemical etching has formed a first channel portion 201 whose channel direction is parallel with the direction of gravity G. Due to the tilt of the surface 12 of the semiconductor 14 such that its surface normal nₛ is at the angle A1 respective to gravity G, the first channel portion 201 is slanted at the angle A1 respective to the surface normal nₛ of the surface 12 of the semiconductor 12. It will also be noted that the metal catalyst 10 has descended under the force of gravity G to be at the bottom of the first channel portion 201. More generally, the metal catalyst will be at the bottom of the etched channel over the course of the metal assisted chemical etching process.

In the examples herein, the semiconductor 14 is silicon (e.g., a silicon wafer 14), the metal catalyst 10 is silver optionally coated with nickel to enhance adhesion, and the etching solution is an H₂/H₂O₂ mixture. However, more generally the semiconductor could be silicon (Si), germanium (Ge), silicon-germanium (Si₁₋ₓGeₓ where 0<x<1), silicon carbide (SiC), gallium nitride (GaN), or so forth; and the etching solution and metal catalyst 10 can be chosen as any combination of etching solution and metal catalyst such that the etching reaction etches the semiconductor with the etching being catalyzed by the chosen metal catalyst (that is, the etching is enabled by the metal catalyst or at least its etching rate is substantially accelerated by the metal catalyst). As some other examples, if the semiconductor is silicon-based (e.g., Si, Si₁₋ₓGeₓ, SiC, et cetera) and the etchant solution is H₂/H₂O₂ then some suitable metal catalysts include: silver, nickel, gold, platinum, palladium, iron, copper, or aluminum.

As previously mentioned, FIG. 3 illustrates the first channel portion 201 after the metal assisted chemical etching has proceeded for the time duration t₁. The length L(t₁) of the etched channel 201 obtained at time t₁ can be written as L(t₁)=R·t₁ where R is the etch rate of the metal assisted chemical etching. In some embodiments, It has been found that the etch rate R in silicon using an H₂/H₂O₂ etch solution and the illustrative Ni-coated Ag catalyst 10 can be greater than 500 nanometers/minute (i.e., 500 nm/min), with a very large aspect ratio greater than 200:1 (where the aspect ratio is the ratio of the channel length L versus the cross-sectional diameter of a cylindrical channel). The actual etch rate R for a given implementation depends on factors such as the H₂/H₂O₂ ratio of the etching solution, the choice of metal catalyst, the temperature of the etchant solution, and so forth, and can be readily calibrated by performing test runs and measuring the obtained channel length using cross-sectional transmission electron microscopy (X-TEM), for example. The cross-section of the channel 201 can be controlled by the area of the metal catalyst 10.

With reference now to FIGS. 4 and 5, the semiconductor 14 has been re-oriented to a new orientation in which the surface normal nₛ of the surface 12 of the semiconductor 14 is now oriented parallel with gravity G. Put another way, at the time t₁ the semiconductor 14 is rotated from its position shown in FIG. 3 to its position shown in FIG. 4. As the first channel portion 201 has already been etched at the time t₁, channel portion 201 remains slanted at the angle A1 relative to the surface normal nₛ of the surface 12 of the semiconductor 14, as indicated in FIG. 4. FIG. 5 then shows the result of continuance of the metal assisted chemical etching from the time t₁ to a later time t₂. During the time interval between t₁ and t₂ a second channel portion 202 is etched, as shown in FIG. 5. The length of the second channel portion 202 is given by R·(t₂−t₁), that is, the product of the etch rate R times the etching time (t₂−t₁) over which the second channel portion 202 is etched. As the metal catalyst 10 descends through the semiconductor 14 in the direction of gravity G throughout the metal assisted chemical etching, the metal catalyst 10 is at the bottom of the channel portion 202 at time t₂, as shown in FIG. 5. The entire etching process from initial immersion in the etchant solution at time to (state shown in FIG. 2) to the time t₂ (state shown in FIG. 5) results in the etching of a bent channel made up of the first channel portion 201 and the second channel portion 202. Due to the change in orientation of the semiconductor 14 at the time t₁ from being tilted at the angle A1 as shown in FIG. 3 to being oriented with its surface normal nₛ, the bent channel includes a bend 203 at the junction of the first channel portion 201 and the second channel portion 202. As previously noted, the first channel portion 201 is slanted at the angle A1 relative to the surface normal nₛ of the surface 12 of the semiconductor 14. On the other hand, the second channel portion 202 is formed with the surface normal nₛ oriented parallel with gravity G, as shown in FIGS. 4 and 5. Hence, the bend 203 of the bent channel is equal to the angle A1.

FIGS. 2-5 present one nonlimiting illustrative example of the disclosed metal assisted chemical etching in which, during at least a portion of the metal assisted chemical etching, the semiconductor 14 is held immersed in the etchant solution with the surface normal nₛ of the surface 12 of the semiconductor 14 at a non-zero angle respective to gravity. It will be appreciated that the approach can more generally produce a channel which is slanted or which is non-linear (e.g., having one or more bends and/or curved portions). Some further examples are described textually in the following.

If only FIGS. 2 and 3 are considered, or to put it another way if the etching is terminated at the time t₁ shown in FIG. 3 by removal of the semiconductor 14 from the etching solution at time t₁, then the result will be a straight channel 201 that is slanted at the angle A1 relative to the surface normal nₛ of the surface 12 of the semiconductor 14. The angle A1 of the slant of the channel 201 relative to the surface normal ns of the surface 12 of the semiconductor 14 is controlled by the tilt of the wafer (assuming the semiconductor 14 is a wafer and the surface 12 is a principle surface thereof), and the slant can be chosen to be any value in the range 0°<A1<90°.

In another example, a channel with a curved portion can be formed by changing the orientation of the semiconductor 14 over a finite non-zero time interval. In the example of FIGS. 2-5, it is assumed that at the time t₁ the semiconductor 14 is rotated instantaneously from its position shown in FIG. 3 to its position shown in FIG. 4, thus producing the bend 203 in the channel shown in FIG. 5. On the other hand, if this rotation was done over a time interval Δt>0 then the bend 203 would instead be a curve. The length L_{curve} of the curve measured along the axis of the channel is given by L_{curve}=R·Δt where R is again the etch rate, and the arc of the curve is effective to change the channel direction from the angle A1 of the first channel portion 201 to the vertical channel direction (i.e., parallel with surface normal nₛ) of the second channel portion 202.

This approach can be extended to produce multiple bends, multiple curved portions, and/or so forth by suitable control of the orientation of the semiconductor 14 over the course of the metal assisted chemical etching. The detailed shape of the resulting channel, including lengths of various channel portions, can be estimated based on the etch rate R which itself can be obtained empirically. In this regard, if the semiconductor 14 is crystalline then there is a possibility the etch rate R could depend on the etch direction respective to the crystallographic coordinates of the semiconductor crystal-in this case, calibration runs can be performed for different angles A1 (e.g. performing the etching of FIGS. 2 and 3 for several different angles A1 aligned with different crystallographic directions and measuring the channel lengths by X-TEM or the like to extract etch rate

$$R = \frac{L}{T}$$

(where here L is the channel length measured by X-TEM and T is the total etch time of the channel).

A channel of any cross-sectional area (e.g., any diameter in the case of a channel with a circular cross-section) can be formed using this approach by using a metal catalyst 10 of correspondingly large cross-sectional area. In another approach for achieving a larger total cross-sectional area, the metal catalyst can be disposed on the surface of the semiconductor as an array of metal catalyst portions, and the metal assisted chemical etching then forms the channel in the semiconductor as an array of channels with each channel corresponding to a metal catalyst portion of the array of metal catalyst portions. As each channel is etched under the same orientation or sequence of orientations of the semiconductor, they will have the same channel direction at each point along their lengths, and hence effectively form a bundle of conductors. This approach of forming an array of channels can be beneficial for achieving a channel of large total cross-sectional area since it may be easier for the aqueous reaction products of the metal assisted chemical etching reaction to migrate out of the metal catalyst-semiconductor interface and flow out the channel being etched to remove semiconductor material (see FIG. 1 part (C)).

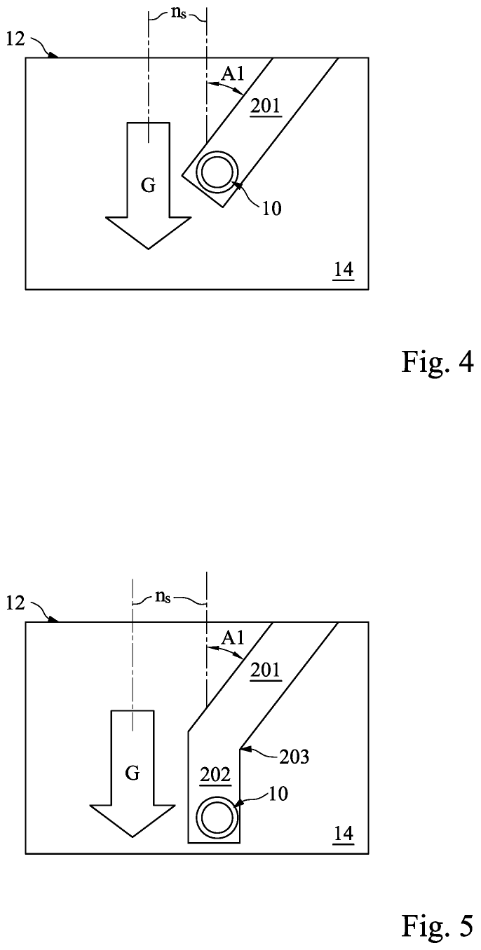

With reference now to FIG. 6, a metal assisted chemical etching method for etching slanted and/or non-linear channels is shown by way of a flowchart. In an operation 40, the metal catalyst 10 is deposited on the surface 12 of the semiconductor 14. This can be done using any suitable deposition method in conjunction with photolithography to define the area of the metal catalyst (or the areas of metal catalyst portions, in the case of forming an array of metal catalyst portions), such as vacuum evaporation, chemical vapor deposition (CVD), physical vapor deposition (PVD), sputtering, or so forth.

In an operation 42, the semiconductor 14 with the metal catalyst 10 deposited on the surface 12 thereof is immersed in the etchant solution, e.g. H₂/H₂O₂ in the illustrative examples. This initiates the metal assisted chemical etching. In an operation 44, during the etching the semiconductor orientation may be adjusted to steer the direction of the channel(s) being formed by the metal assisted chemical etching. It is noted that the operation 44 may include an initial tilted orientation during the immersion 42—this is shown for example in FIGS. 2 and 3 where the semiconductor 14 is tilted on initial immersion, that is, held at a nonzero value of the angle A1 respective to gravity as the semiconductor 14 is immersed in the etching solution.

When the etching is complete, in an operation 46 the semiconductor 14 is removed from the etching solution to terminate the etching. Optionally, the operation 46 may include a rinse dip or the like to ensure rapid removal of any residual etchant solution to ensure termination of the metal assisted chemical etching.

After completion of the metal assisted chemical etching process of FIG. 6, the semiconductor (e.g. silicon wafer) typically will undergo further processing. For example, if the channel is intended to be filled with an electrically conductive material to form an electrical via, then CVD, PVD, or another deposition process can be performed to fill the channel 20 with the desired metal or other electrically conductive material.

In the foregoing examples, the channel formed by the metal assisted chemical etching is controlled by gravity by way of controlling orientation of the semiconductor 14 with respect to gravity. Additionally, or alternatively, a magnetic field may be applied to the semiconductor 14 to attract the metal catalyst 10 (assumed here to comprise a magnetic material) during the metal assisted chemical etching. If the force of the magnetic attraction on the metal catalyst 10 is parallel with gravity, then the magnetic field can strengthen the overall directional guiding force applied to the metal catalyst 10. On the other hand, if the magnetic field is applied in a different direction than gravity then the combined gravitational and magnetic forces will determine the direction of movement of the metal catalyst 10 and hence the direction of the etched channel. As the strength and direction of the magnetic field can be switched rapidly (e.g., using an array of electromagnets disposed around the container containing the etchant solution 32), this can provide more rapid directional changes during the channel etching.

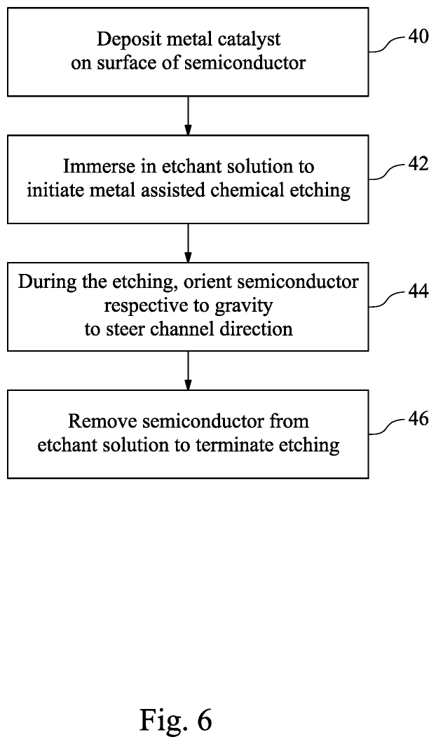

With reference now to FIG. 7, one nonlimiting illustrative example of a suitable semiconductor process tool for implementing etching of nonlinear channels by metal assisted chemical etching with controlled orientation of the semiconductor in the context of an automated semiconductor manufacturing process workflow is described. The tool suitably receives a batch of semiconductor wafers for processing transported in includes a front-opening unified pod (FOUP) 50. FIG. 7 illustrates a single semiconductor wafer 14, but more commonly the FOUP 50 will carry a batch of semiconductor wafers. The semiconductor wafer(s) 14 may be, for example, silicon wafers on which an integrated circuit (IC), imaging array, or other electronic device die or dice is/are being fabricated. Note that the silicon wafer could be a bulk silicon wafer, or could be a silicon-on-insulator (SOI) wafer or the like. Although not shown, it is to be understood that the semiconductor wafer(s) 14 have previously had the metal catalyst 10 (optionally comprising an array of metal catalyst portions) disposed on the top principle surface thereof. This metal catalyst deposition was suitably previously performed using a CVD tool, PVD tool, or other suitable deposition tool of the semiconductor fabrication facility. To initiate processing of a semiconductor wafer 14, a wafer transfer robot 52 picks up the target wafer from the FOUP 50 and transfers it to a transfer station 54. The transfer station 54 may optionally implement preprocessing such as heating or cooling of the semiconductor wafer 14 to bring it to a design-basis temperature in preparation for the metal assisted chemical etching. This is beneficial since the etch rate R of the metal assisted chemical etching can be temperature-dependent.

The wafer is then transferred to the apparatus 30 for controlling the orientation of the semiconductor 14 previously discussed in general terms with reference to FIG. 1 part (E). In the illustrative fabrication tool embodiment of FIG. 7, this apparatus 30 comprises a robot that is configured by a movable arm or the like to lift the semiconductor wafer 14 off the transfer station 54 and move it to a position above the etchant solution 32 (also illustrated previously in FIG. 1 part (E)). The etchant solution 32 is typically an aqueous solution such as an aqueous H₂/H₂O₂ solution, which is in a liquid phase and contained in a suitable container. The robotic apparatus 30 is further configured to lower the semiconductor wafer 14 into the etchant solution 30 while tilting the wafer by moving a lever arm 36 about the pivot 34 (also illustrated previously in FIG. 1 part (E)). To implement the operations 42, 44, and 46 of the method of FIG. 6, a horizontal arm 38 bearing the lever arm 36 via the pivot 34 is suitably lowered via a vertical elevator 39 until the wafer 14 is immersed in the etchant solution 32. If the initial channel direction is to be slanted (i.e., angle A1 is nonzero, see FIGS. 2 and 3), then as part of the operation 44 the pivot is operated to set the lever arm 36 at the appropriate angle before the wafer 14 is immersed. Thereafter, the operation 44 controls the pivot 34 to adjust the orientation of the wafer 14 in accordance with a predetermined orientation sequence for implementing the desired bends, curves, or other nonlinear features of the channel. After the channel etching is complete, the elevator 39 is operated to raise the wafer 14 until it is no longer immersed in the etchant solution 32, and the robotic apparatus 30 then transfers the wafer back to the transfer station 54. In some embodiments, the transfer station 54 may be a cooling station that cools the wafer 14 to ensure termination of the metal assisted chemical etching. (This approach can be effective if the etch rate R of the metal assisted chemical etching is strongly temperature dependent and decreases quickly with lower temperature).

With reference now to FIGS. 8 and 9, one nonlimiting illustrative example of a fixture 301 suitably included on the end of the lever arm 36 to hold the wafer 14 is illustrated. The illustrative fixture 301 is similar to a type of fixture used in some electrochemical plating (ECP) tools, and includes four arms 302 for holding the wafer 14 at its outer periphery at four points at 90 degree intervals around the circumference of the wafer 14. As seen in FIG. 9, the distal end of each arm 302 includes an extensible inner arm 304 ending in a slotted holding element 306. The inner arms 304 of the arms 302 are extended to place the holding elements 306 around the periphery of the semiconductor wafer 14, and then the inner arms 304 are retracted to cause the holding elements 306 to engage the edges of the wafer 14. In some nonlimiting illustrative examples, the body of the illustrative fixture 301 comprises a nickel-based alloy such as Hastelloy® (Haynes International Inc.).

It will be appreciated that the fabrication tool described with reference to FIGS. 7-9 is merely a nonlimiting illustrative example, and numerous robotic mechanisms can be employed to enable controlling the orientation of the semiconductor wafer 14 respective to gravity during the metal assisted chemical etching in order to control the direction of the channel being etched. In the illustrative embodiments, there is a single pivot 34, which allows controlling the tilt of the wafer respective to a single axis. However, in some contemplated embodiments the robotic apparatus could include two orthogonal tilt mechanisms (e.g., X- and Y-tilt control) which could be used in tandem to control the direction of the etched channel in any desired direction.

On the other hand, if the goal is to etch a straight slanted channel (e.g., to etch only the channel 201 illustrated by FIGS. 2 and 3), then the apparatus could achieve the tilt of the immersed wafer needed for the desired channel slant by including a wedge or other tilted bottom to the container holding the etching solution and placing the wafer on that wedge or tilted container bottom during the metal assisted chemical etching.

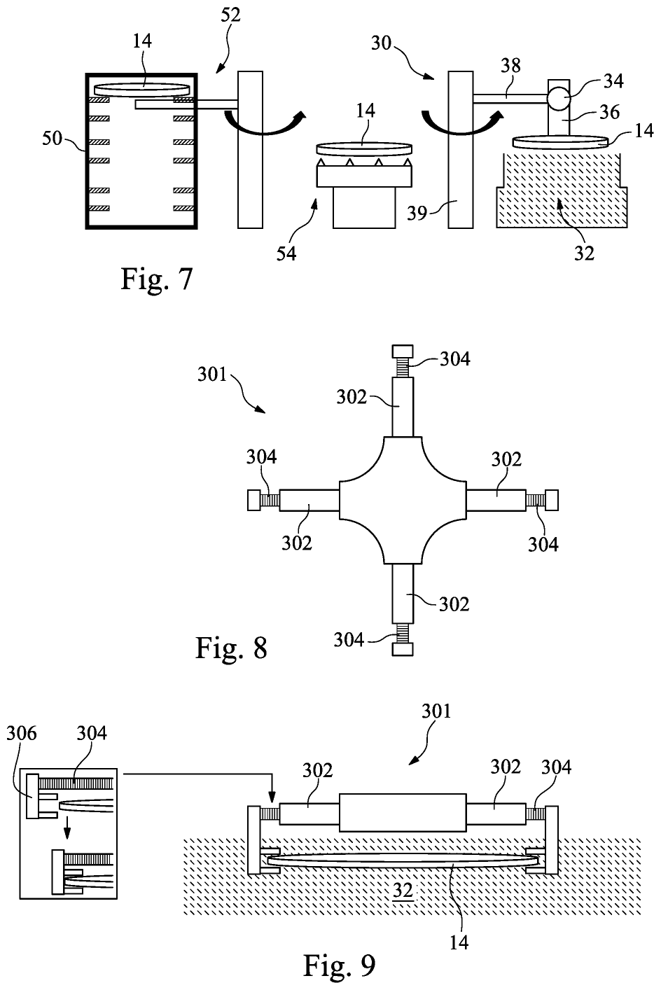

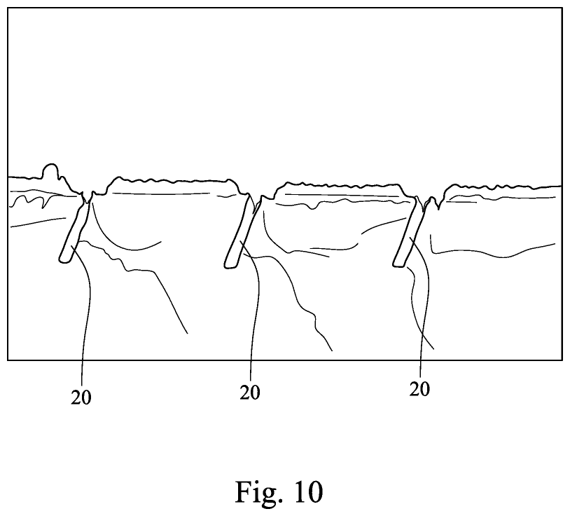

With reference to FIGS. 10 and 11, the disclosed metal assisted chemical etching of slanted and/or non-linear channels has been implemented and its effectiveness has been verified by way of XTEM imaging. FIG. 10 illustrates the geometry of straight slanted channels 20 formed in silicon using a nickel-coated silver metal catalyst as observed under XTEM. FIG. 11 illustrates the geometry of an array of nonlinear channels, formed in silicon using an array of nickel-coated silver metal catalyst portions as observed under XTEM. In the example of FIG. 11, the density of silver metal catalyst portions was high enough that they formed dense channel pores, thus forming what can be considered to be a nonlinear silicon nanowire (SiNW) array.

It will be appreciated that the disclosed metal assisted chemical etching of slanted and/or non-linear channels can be usefully employed in a wide range of workflows for fabricating ICs, imaging arrays, and so forth.

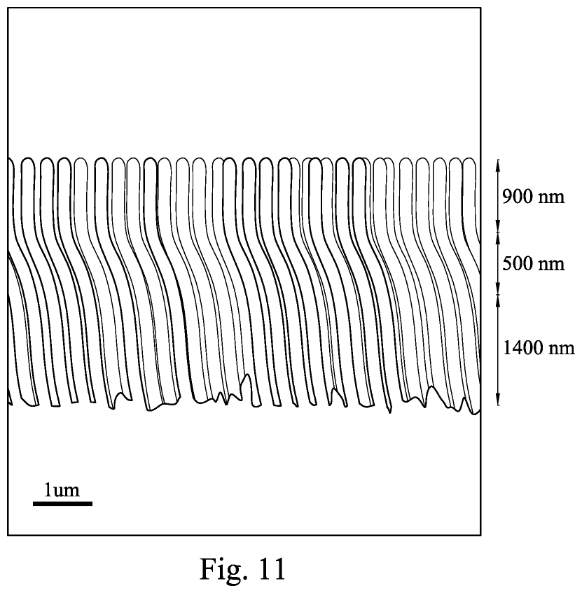

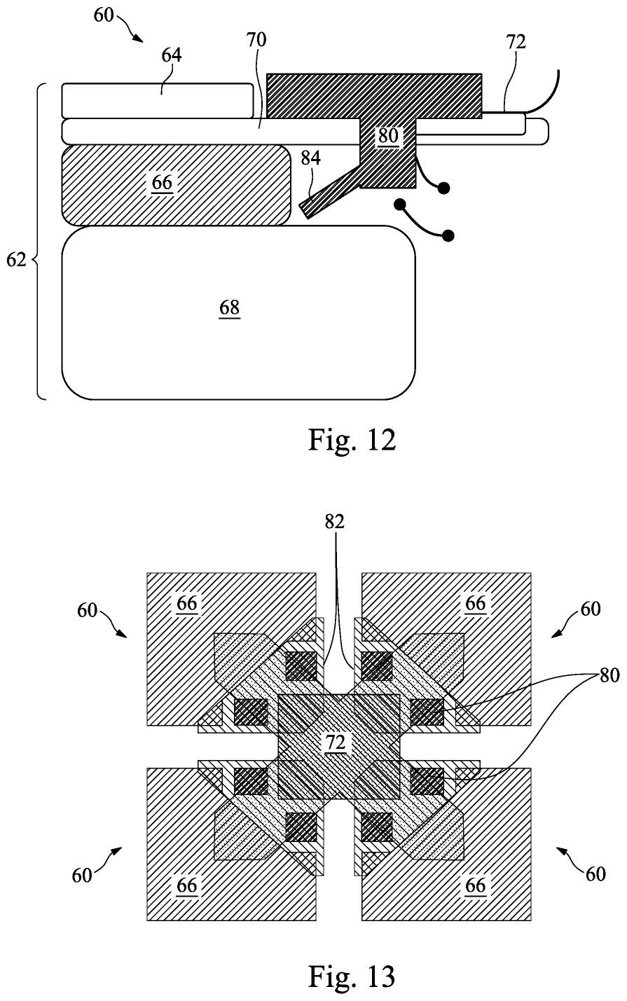

With reference now to FIGS. 12 and 13, a complementary metal-oxide-semiconductor (CMOS) image sensor employing a slanted and/or non-linear channel as disclosed herein is described. As seen in the cross-sectional view of FIG. 12, a CMOS image sensor 60 includes a photodiode 62. In the illustrative example, the photodiode 62 includes a P-type region 64 referred to herein as a P-type pinned photodiode (PPPD) 64, and an N-type region divided into a first N-type sub-region 66 referred to herein as an N-type pinned photodiode (NPPD) 66 and a second N-type sub-region 68 referred to herein as a deep N-type pinned photodiode (DNPPD) 68. In the illustrative example, a transfer gate buried channel (TXBC) layer 70 is disposed between the PPPD 62 and the NPPD 64. The optional TXBC layer 70 may, for example, be arsenic (As) based, and facilitates electron transfer. It is to be understood that the photodiode 62 is merely an illustrative example, and other photodiode architectures are contemplated.

FIG. 13 shows a top view of a nonlimiting illustrative layout in which of the four CMOS image sensors 60 of FIG. 12 share a common N-type doped region 72 which may be electrically connected to various devices, such as a source follower transistor, a reset transistor, a row select transistor, or the like. It should be noted that FIG. 13 provides a nonlimiting illustrative layout, and other groupings of the CMOS image sensors 60 of an image sensor array are contemplated.

In operation, the photodiode 62 accumulates photoelectrons during a light exposure interval. The photodiode 62 accumulates photoelectrons in deep layers, e.g. the NPPD layer 66 and the DNPPD layer 68. To transfer the accumulated photoelectrons out of these deep layers 66 and 68, at least one vertical transfer gate (VTG) 80 is positioned proximate to the photodiode 62, penetrating to a depth sufficient to be proximate to the deep layers 66 and 68. FIG. 13 illustrates a nonlimiting example in which each CMOS image sensor 60 includes two VTG 80. FIG. 13 also illustrates a gate electrode 82 made of a suitable material such as polysilicon or the like.

This type of design employing a photodiode with deep layers and photocharge transfer via a VTG (or multiple VTG) have advantages in terms of miniaturization, as the depth enables the area of the photodiode to be reduced while still accumulating sufficient photocharge due to the depth of the photodiode to achieve the same or even higher color saturation. However, using a VTG to transfer photoelectrons out of deep layers of a photodiode is not easy. Formation of a VTG entails through-silicon via (TSV) and deep trench isolation processes, for example including plasma etching, which can damage the silicon material proximate to the photodiode where the photoelectrons pass during transfer. This can result in degraded white pixel (WP) performance, and calls for very precise profile and depth control when fabricating the VTG, which can be difficult to achieve.

As seen in FIG. 12, a slanted and/or non-linear channel formed by metal assisted chemical etching as disclosed herein can enable formation of a slanted protrusion 84 of the VTG 80 toward the photodiode 62. The slanted portion 84 of the VTG 80 has a proximal end connected with the vertical portion of the VTG 80 and has a distal end that is closer to the photodiode 62 than the proximal end. By forming the slanted protrusion 84 by metal assisted chemical etching as disclosed herein, the bulk of the VTG 80 can be located further away from the photodiode 62, so that VTG fabrication profile and depth control can be relaxed and any silicon damage produced during the fabrication of the VTG 80 is less likely to adversely impact performance of the CMOS image sensor 60. The end of the slanted protrusion 84 is the portion of the overall VTG 80 that is proximate to the photodiode 62, and this is formed by wet etching (specifically metal assisted chemical etching), so that plasma damage of the silicon is reduced or avoided entirely. Additionally, the slanted profile of the slanted protrusion 84 can improve full well capacity (FWC) and pixel WP performance. Thus, collection of the photoelectric charge accumulated in the photodiode 62 by the VTG 80 is enhanced by the slanted protrusion 84

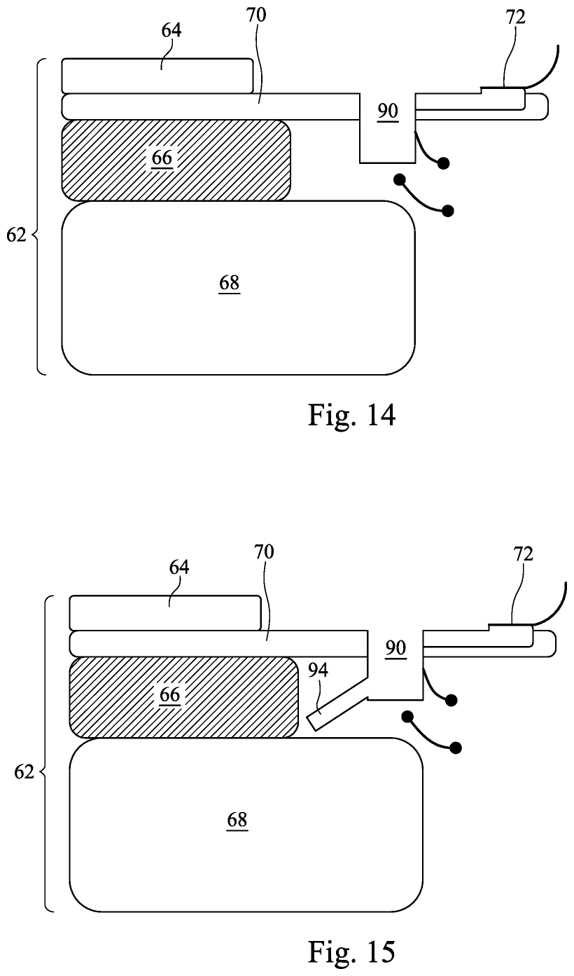

With reference now to FIGS. 14 and 15, fabrication of the VTG 80 with its slanted protrusion 84 is described. First, as shown in FIG. 14, a channel 90 corresponding to the vertical portion of the VTG 80 is etched. Next, as shown in FIG. 15, a slanted channel 94 corresponding to the slanted VTG protrusion 84 is etched. The etched channels 90 and 94 are connected as seen in FIG. 15. Finally, the conductive material making up the VTG 80 is disposed in the channels 90 and 94 by a suitable technique such as CVD, PVD, or so forth to form the VTG 80 its slanted protrusion 84 as in FIG. 12.

In one approach, the channel 90 is first etched into the silicon by plasma etching, analogously to the conventional approach for fabricating a VTG. Thereafter, the metal catalyst (e.g., nickel-coated silver) is disposed on the surface of the semiconductor exposed at the distal end of the channel 90, and metal assisted chemical etching is employed with the wafer at a suitable tilt (i.e., a nonzero angle A1 as shown in FIGS. 2 and 3) to etch the slanted channel 94 corresponding to the slanted VTG protrusion 84.

In another approach, both channels 90 and 94 are formed by metal assisted chemical etching. In this approach, the metal catalyst (e.g., nickel-coated silver) is disposed on the surface of the wafer before the etching of the channel 90. Metal assisted chemical etching is then performed with the normal of the wafer surface oriented parallel with gravity (i.e., with a zero angle between surface normal nₛ of the wafer surface and gravity) to etch the channel 90. Then, the wafer orientation is tilted to a nonzero angle to cause the continued metal assisted wet chemical etching to etch the slanted channel 94. Note that in this embodiment the cross-sectional diameters of both channels 90 and 94 is about the same, corresponding to the size of the metal catalyst (or to the area of the array of metal catalyst portions if this approach is used).

In the following, some further embodiments are described.

In a nonlimiting illustrative embodiment, a method is disclosed of fabricating a semiconductor structure. The method includes: disposing a metal catalyst on a surface of a semiconductor; and after the disposing, performing metal assisted chemical etching including holding the semiconductor immersed in an etchant solution and catalyzing an etching chemical reaction between the etchant solution and the semiconductor using the metal catalyst to etch the semiconductor to form a channel in the semiconductor. During at least a portion of the metal assisted chemical etching the semiconductor is held immersed in the etchant solution with a surface normal of the surface of the semiconductor at a non-zero angle respective to gravity. In some embodiments, an orientation of the semiconductor is changed during the metal assisted chemical etching to form the channel in the semiconductor with at least one bend or curved portion.

In a nonlimiting illustrative embodiment, a method is disclosed of fabricating a semiconductor structure. The method includes disposing a metal catalyst on a surface of a silicon wafer, and, after the disposing, etching a channel in the silicon wafer using a hydrogen fluoride/hydrogen peroxide (HF/H₂O₂) etching solution catalyzed by the metal catalyst. During the etching, a direction of the channel is controlled by controlling an orientation of the silicon wafer respective to gravity.

In a nonlimiting illustrative embodiment, an image sensor comprises: a photodiode formed in a semiconductor; and a vertical transfer gate formed in the semiconductor, the vertical transfer gate including a vertical portion and a slanted portion. The slanted portion of the vertical transfer gate has a proximal end connected with the vertical portion of the vertical transfer gate and has a distal end that is closer to the photodiode than the proximal end. In some embodiments, the semiconductor is silicon and the image sensor is a CMOS image sensor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor structure, the method comprising:
disposing a metal catalyst on a surface of a semiconductor; and
after the disposing, performing metal assisted chemical etching including holding the semiconductor immersed in an etchant solution and catalyzing an etching chemical reaction between the etchant solution and the semiconductor using the metal catalyst to etch the semiconductor to form a channel in the semiconductor;
wherein during at least a portion of the metal assisted chemical etching the semiconductor is held immersed in the etchant solution with a surface normal of the surface of the semiconductor at a non-zero angle respective to gravity.

2. The method of claim 1 wherein the holding of the semiconductor immersed in the etchant solution comprises:
holding the semiconductor with the surface normal of the surface of the semiconductor at a single fixed non-zero angle respective to gravity throughout the metal assisted chemical etching to form the channel in the semiconductor as a straight channel with a non-zero channel direction respective to the surface normal of the surface of the semiconductor.

3. The method of claim 1 wherein the holding of the semiconductor immersed in the etchant solution comprises:
over a first time period, holding the semiconductor with the surface normal of the surface of the semiconductor at a first angle respective to gravity to form a first portion of the channel with a first channel direction respective to the surface normal of the surface of the semiconductor; and
over a second time period, holding the semiconductor with the surface normal of the surface of the semiconductor at a second angle respective to gravity to form a second portion of the channel with a second channel direction respective to the surface normal of the surface of the semiconductor;
wherein the first angle respective to the surface normal of the surface of the semiconductor is different from the second angle respective to the surface normal of the surface of the semiconductor, and the first channel direction is different from the second channel direction.

4. The method of claim 1 wherein the holding of the semiconductor immersed in the etchant solution comprises:
changing an orientation of the semiconductor during the metal assisted chemical etching to form the channel in the semiconductor with at least one bend.

5. The method of claim 1 wherein the holding of the semiconductor immersed in the etchant solution comprises:
changing an orientation of the semiconductor during the metal assisted chemical etching to form the channel in the semiconductor with at least one curved portion.

6. The method of claim 1 wherein the holding of the semiconductor immersed in the etchant solution comprises:
the holding of the semiconductor immersed in the etchant solution using a mount having at least one joint configured to adjust a tilt of the surface of the semiconductor respective to gravity.

7. The method of claim 1 further comprising:
during the metal assisted chemical etching, applying a magnetic field to the semiconductor to attract the metal catalyst.

8. The method of claim 1 wherein the metal catalyst is disposed on the surface of a semiconductor as an array of metal catalyst portions, and the metal assisted chemical etching forms the channel in the semiconductor as an array of channels with each channel corresponding to a metal catalyst portion of the array of metal catalyst portions.

9. The method of claim 1 wherein the semiconductor comprises silicon and the etchant solution comprises a mixture of hydrogen fluoride (HF) and hydrogen peroxide (H₂O₂).

10. The method of claim 9 wherein the metal catalyst comprises silver.

11. The method of claim 10 further comprising:
forming an image sensor in the silicon including a photodiode and a vertical transfer gate comprising an electrically conductive material, wherein the vertical transfer gate is formed after the metal assisted chemical etching, and the forming of the vertical transfer gate includes filling the channel in the silicon with the electrically conductive material to form a protrusion of the vertical transfer gate toward the photodiode.

12. A method of fabricating a semiconductor structure, the method comprising:
disposing a metal catalyst on a surface of a silicon wafer; and
after the disposing, etching a channel in the silicon wafer using a hydrogen fluoride/hydrogen peroxide (HF/H₂O₂) etching solution catalyzed by the metal catalyst; and
during the etching, controlling a direction of the channel by controlling an orientation of the silicon wafer respective to gravity.

13. The method of claim 12 wherein the controlling comprises:
holding the silicon wafer in a fixed tilted orientation respective to gravity to etch the channel consisting of a straight channel with a non-zero channel direction respective to a surface normal of the surface of the silicon wafer.

14. The method of claim 12 wherein the controlling comprises:
over a first time period of the etching, holding the silicon wafer in a first orientation respective to gravity to etch a first portion of the channel; and
over a second time period of the etching, holding the silicon wafer in a second orientation respective to gravity different from the first orientation to etch a second portion of the channel in a different direction than the first portion of the channel.

15. The method of claim 12 wherein the controlling comprises:
changing an orientation of the silicon wafer respective to gravity during the etching to form a curved portion of the channel.

16. The method of claim 12 wherein the metal catalyst comprises silver.

17. The method of claim 12 further comprising applying a magnetic field to the semiconductor during the metal assisted chemical etching to attract the metal catalyst.

18. The method of claim 12 further comprising:
forming a complementary metal oxide semiconductor (CMOS) image sensor including forming a photodiode in the silicon wafer and forming a vertical transfer gate comprising an electrically conductive material;
wherein the vertical transfer gate includes a vertical portion and a slanted portion, the slanted portion being formed by filling the channel with a portion of the electrically conductive material; and
wherein the slanted portion of the vertical transfer gate has a proximal end connected with the vertical portion of the vertical transfer gate and has a distal end that is closer to the photodiode than the proximal end.

19. An image sensor comprising:
a photodiode formed in a semiconductor; and
a vertical transfer gate formed in the semiconductor, the vertical transfer gate including a vertical portion and a slanted portion;
wherein the slanted portion of the vertical transfer gate has a proximal end connected with the vertical portion of the vertical transfer gate and has a distal end that is closer to the photodiode than the proximal end.

20. The image sensor of claim 19, wherein the semiconductor is silicon and the image sensor is a complementary metal oxide semiconductor (CMOS) image sensor.
